(19) United States
(12) Patent Application Publication
(10) Pub. No.: US 2005/0210665 A1
(43) Pub. Date: Sep. 29, 2005

(54) Tray for storing and transporting semi-conductor and other microelectronic components

(76) Inventors: James R. Nigg, Howard Lake, MN (US); Will D. Harrison, Chaska, MN (US)

Correspondence Address: PATTERSON, THUENTE, SKAAR & CHRISTENSEN, P.A., 4800 IDS CENTER, 80 SOUTH 8TH STREET, MINNEAPOLIS, MN, 55402-2100, US

(21) Appl. No.: 10/811,321

(22) Filed: Mar. 25, 2004

(51) Int. Cl. G01R 1/00

(52) U.S. Cl. 29/739; 29/721

(57) ABSTRACT

A chip tray of the present invention includes on its underside a resilient sheet member that resiliently retains microelectronic components in the chip tray below by pressing gently but firmly down on the microelectronic components and the separators between cavities that contain the components.

### FIELD OF THE INVENTION

The present invention relates to a tray for storing and transporting miniature electronic components, commonly known as a chip trays.

### BACKGROUND OF THE INVENTION

Microelectronic components go through many processing steps during their manufacturer. Microelectronic components have been getting smaller and smaller as time goes by. Commonly, in fabricating facilities microelectronic components such as chips and other components are transported in trays. Generally the trays have numerous form fitting compartments so that numerous microelectronic components can be handled and transported at one time. Generally, so called chip trays are designed to be stackable so that multiple trays can be transported. Thus one chip tray forms the cover for the chip tray immediately below it. When a desired number of trays are stacked for transport a dedicated cover is applied to the top tray to keep the components covered and secure.

As microelectronic components have become smaller they have become more difficult to handle. In particular some microelectronic components have become so small that their overall size is less than the tolerances that can reasonably be attained in the manufacturing of chip trays. Thus it has become prohibitively difficult and expensive to manufacture form fitting chip trays with tight fitting lids that are sufficiently close to the microelectronic components to keep them from shifting while the chip tray is in transit.

In the past, several materials have been interposed between chip trays in an effort to keep components in place. These materials include rice paper, Tyvek® and various films about three to seven mils thick. These components have mixed success in the retention of very small components.

Thus it would be a benefit to the microelectronics industry to have access to a chip tray with a lid that would provide for excellent retention of extremely small microelectronic components while at the same time preventing those microelectronic components from being damaged.

### SUMMARY OF THE INVENTION

The present invention is a chip tray that solves many of the above-mentioned problems. The chip tray of the present invention includes on its underside a resiliently compressible sheet member that resiliently retains microelectronic components in the chip tray below by pressing gently but firmly down on the microelectronic components and the separators between cavities that contain the components. The surface of compressible sheet member that confronts the top of the chip tray and component either extends slightly into the pocket to secure the component or is indented to conform to the component contour that extends above the top surface of the tray.

The chip tray of the present invention generally includes a central plate having an upper surface and a lower surface and a supporting perimeter structure or legs. The invention may be utilized with stackable chip trays or chip tray lids of any configuration. The upper surface of the plate generally includes a plurality of indented form fitting cavities into which microelectronic components may fit. Each cavity is molded appropriately to support and contain a specific microelectronic component. The lower surface of the chip tray or cover of the present invention is covered by a resilient sheet layer. The resilient sheet layer may be formed, for example, by open or close cell resilient foam. The resilient sheet like member may include memory foam, an elastomeric polymer, polyethylene foam or a static dissipative cross-linked polyethylene foam. Some foams appropriate for this use are described in U.S. patent application Ser. No. 09/971,352 and U.S. Pat. No. 6,286,684B1 both of which are incorporated herein in their entirety by this reference.

The resilient sheet layer is desirably held to the lower surface of the chip tray by an adhesive but may be mechanically secured to the lid or unsecured and separate from the tray or lid. If the resilient sheet layer is adhesively secure to the chip tray, the adhesive may be selected from contact adhesives, low ionic double-faced tape, or a heat sensitive adhesive such as a hot melt adhesive may be used as well.

The resilient sheet is selected so that it will be compressed slightly when placed on top of a chip tray filled with microelectronic components thus providing a gentle but firm holding force to keep the microelectronic components in their desired cavities. Desirably the resilient sheet layer deflects by at least about ten percent of its thickness when applied to the chip tray component cavities. For example, for a tray that has a space of 0.08 inch between adjacent trays the resilient layer may be chosen to be about 0.10 inch thick allowing for a compression of 0.02 inch. A desirable range of compression is from five to twenty five percent of the thickness of the resilient layer or from 0.01 to 0.05 inch.

An advantage and feature of particular embodiments is that a chip tray is provided that is capable of securing different size components, particularly components with different heights in the pockets of the chip tray.

A further advantage and feature of the invention is that the components are gently secured in the pockets of the chip tray and sliding and rattling of the components in the pocket is minimized or eliminated.

A further advantage and feature of the invention is that the foam material can be static dissipative to minimize potential for damage from static electricity.

### BRIEF DESCRIPTION OF THE DRAWINGS

FIG. 1 is a top plan view of a chip tray in accordance with the present invention.

FIG. 2 is a cross sectional view taken along section line 2-2 of FIG. 1.

FIG. 3 is a detailed cross sectional view taken from detail A of FIG. 2.

FIG. 4 is a cross sectional view of two stacked chip trays depicting a resilient layer retaining a microelectronic component.

FIG. 5 is a detailed cross sectional view of two stacked chip trays depicting a resilient layer retaining a microelectronic component and resiliently extending into a cavity containing the microelectronic component.

FIG. 6 is a cross sectional view of two stacked chip trays and a chip tray cover depicting two resilient layers retaining microelectronic components.

FIG. 7 is a cross sectional view of a chip tray and cover in accordance with an embodiment of the invention.

### DETAILED DESCRIPTION OF THE INVENTION

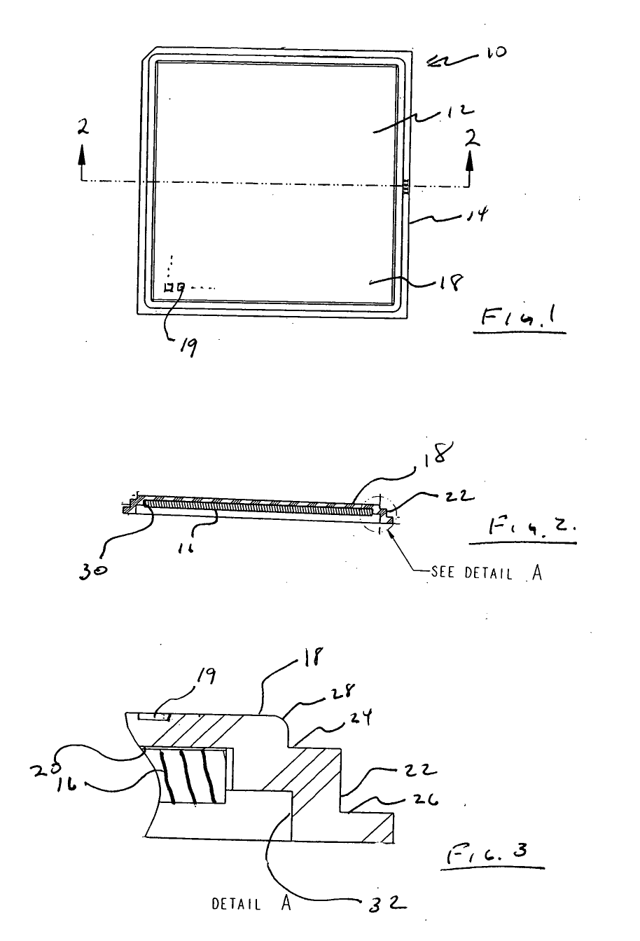

The microelectronics transport tray 10 of the present invention as depicted in FIGS. 1-3 generally includes a body portion or plate 12, a rail or plate surround 14 and a resiliently compressible sheet member 16.

Plate 12 generally includes a top surface 18 and a bottom surface 20. Plate 12 is depicted herein as a square shape but plate 12 may take any shape desired. Top surface 18 will generally include a plurality or multiplicity of cavities 19 which are shaped and sized to accept a particular microelectronic component and that have a matrixical arrangement on the top surface. The microelectronics transport tray 10 as described in this application is exemplary. The present invention may be utilized with other stackable microelectronics transport tray 10 or lid 21. The use of the invention with a lid will be readily apparent to those skilled in the art.

Plate 12 is bound on its perimeter by plate support 14. Plate surround 14 generally supports plate 12 in such a way that microelectronics transport tray 10 is stackable upon a similar tray 10. In this embodiment of the invention plate surround includes leg 22. Leg 22 is configured so as to extend downward and outward from plate 12 in a stair step fashion. Thus in this embodiment of the invention leg 22 defines, on its upper surface, first indentation 24 and second indentation 26. Desirably plate 12 also defines rounded corner 28. While the embodiment disclosed here is supported by plate surround 14, it is to be understood that the present invention can make use of any sort of support member including legs, pegs or protrusions to support microelectronics transport tray 10 in a stackable fashion upon similar microelectronics transport tray 10.

Bottom surface 20 of tray 10 defines flat recess 30 and indented perimeter 32. Flat recess 30 desirably covers the bottom of plate 12 entirely. Resilient sheet 16 is desirably received into flat recess 30. Resilient sheet 16 covers substantially all of flat recess 30. Resilient sheet 16 has a thickness slightly greater than the depth of flat recess 30 so that resilient sheet 16 when received in flat recess 30 extends beyond the depth of flat recess 30 slightly.

Resilient sheet 16 is desirably formed of an open or closed cell cell resilient polymer foam. However, resilient sheet 16 may be formed of any resilient material that will provide a yielding resilient surface appropriate to apply a small force to microelectronic components transported in tray 10. The resilient sheet member may include memory foam, an elastomeric polymer, polyethylene foam or static dissipative cross-linked polyethylene foam.

Resilient sheet 16 may be secured to flat recess 30 by adhesive or mechanical means. For example, resilient sheet 16 may be secured by a contact adhesives, low ionic double-faced tape, or a heat sensitive adhesive such as a hot melt adhesive may be used as well. In some applications it may be contagious to secure resilient sheet 16 to tray 10 with a hot melt adhesive so that it is necessary and desired for cleaning resilient sheet 16 can be released from flat recess 30 by appropriate heating.

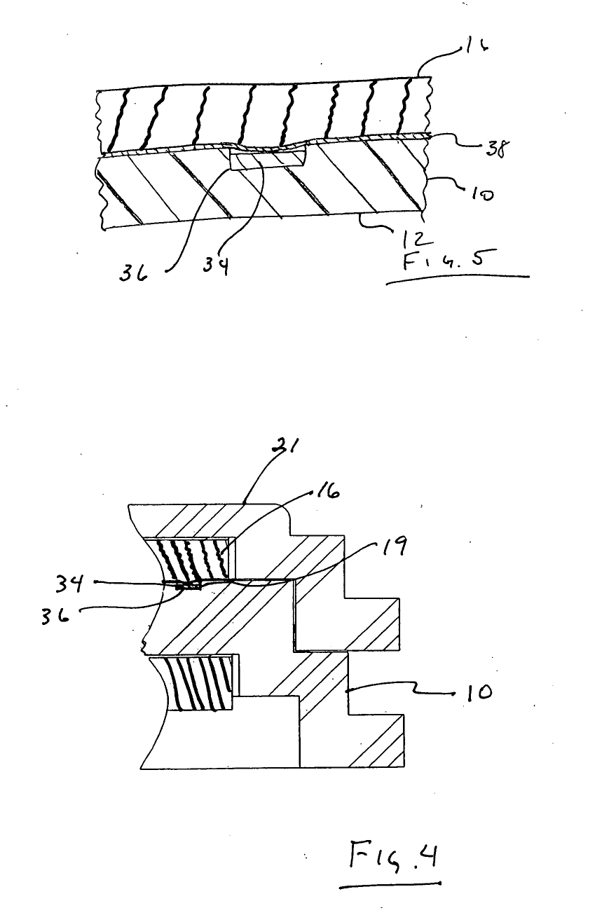

Referring to FIG. 4, two microelectronics transport trays 10 are shown in a stacked orientation with a microelectronic component 34 therebetween. Microelectronic component 34 rests in form fitting cavity 36 and is held in place by resilient sheet 16 pressing down there upon.

Referring to FIG. 5, a membrane 38 may be interposed between resilient sheet 16 and microelectronic component 34. Membrane 38 may be bonded to resilient sheet 16 or be interposed as a separate layer. Note that resilient sheet 16 deforms and extends into cavity 36 to a small degree. This deformation helps to assure that microelectronic component 34 is securely and safely held within cavity 36 thus preventing potential damage to microelectronic component 34 while in transit.

Referring to FIG. 6, two microelectronics transport trays 10 are shown in a stacked orientation with a microelectronic component 34 therebetween. In addition, tray lid 21 covers the upper of the two microelectronics transport trays 10. Both microelectronics transport trays 10 and tray lid 21 are provided with resilient sheet 16 to protect microelectronic components 34 contained therebetween.

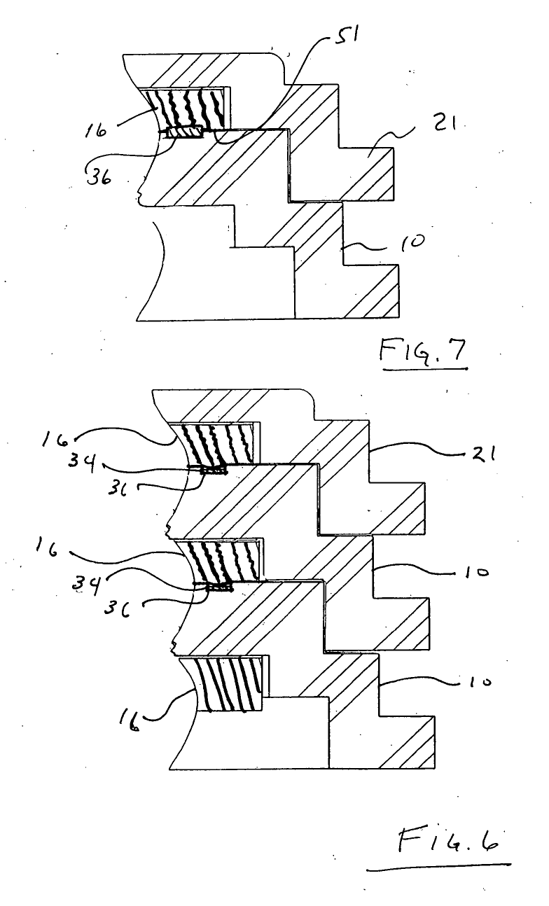

Referring to FIG. 7, is a cross sectional view of a chip tray 10 and cover 21 with the component 34 having a thickness greater that the pocket height and the resiliently compressible sheet member downward surface 51 deflected to absorb the contour of the component.

1. A microelectronic transport tray for containing and transporting microelectronic components, the tray comprising:
a plate supported by a plate surround;
the plate including form fitting cavities arranged in a matrix defined therein to contain microelectronic components; and
a resilient sheet adjacent the bottom side of the plate such that when two said microelectronics transport trays are stacked the resilient sheet secures the microelectronic components resiliently therebetween and in the form fitting cavities.

2. The microelectronic transport tray as claimed in claim 1, in which the resilient sheet comprises a material chosen from a group consisting of memory foam, an air bag, an elastomeric polymer, polyethylene foam and static dissipative cross-linked polyethylene foam.

3. The microelectronic transport tray as claimed in claim 1, in which the resilient sheet is secured to the bottom of the plate.

4. The microelectronic transport tray as claimed in claim 3, in which the resilient sheet is secured to the bottom of the plate by an adhesive.

5. The microelectronic transport tray as claimed in claim 3, in which the resilient sheet is mechanically secured to the bottom of the plate.

6. The microelectronic transport tray as claimed in claim 4, in which the adhesive is selected from a group consisting of a contact adhesive, a low ionic double-faced adhesive tape, a heat sensitive adhesive and a hot melt adhesive.

7. The microelectronic transport tray as claimed in claim 1, in which the resilient sheet is compressed when the when two said microelectronics transport trays are stacked.

8. The microelectronic transport tray as claimed in claim 7, in which the resilient sheet is compressed between about five percent and twenty five percent of its thickness.

9. The microelectronic transport tray as claimed in claim 7, in which the resilient sheet is compressed between about 0.01 inch and 0.05 inch.

10. The microelectronic transport tray as claimed in claim 7, in which the resilient layer comprises a static dissipative cross-linked polyethylene foam.

11. A method of protecting microelectronic components comprising the steps of:
placing the microelectronic components into form fitting cavities in a first chip tray;
placing a second chip tray or a chip tray cover on top of the first chip tray; and
interposing a resilient sheet between the second chip tray or the chip tray cover and the first chip tray such that the resilient sheet is compressed between the second chip tray or the chip tray cover and the first chip tray thus holding the microelectronic components in the form fitting cavities.

12. The method as claimed in claim 11, further comprising the steps of:
selecting the second chip tray or the chip tray cover and the first chip tray so that there is a predetermined space between the second chip tray or the chip tray cover and the first chip tray; and
selecting the resilient sheet to have a thickness slightly greater than the space between the second chip tray or the chip tray cover and the first chip tray.

13. The method as claimed in claim 11, further comprising the step of selecting the resilient layer from a group consisting of memory foam, an air bag, an elastomeric polymer, polyethylene foam and static dissipative cross-linked polyethylene foam.

14. The method as claimed in claim 11, further comprising the step of securing the resilient sheet to a bottom of the second chip tray or the chip tray cover.

15. The method as claimed in claim 11, further comprising the step of securing the resilient sheet to a bottom of the second chip tray or the chip tray cover with an adhesive.

16. The method as claimed in claim 11, further comprising the step of securing the resilient sheet to a bottom of the second chip tray or the chip tray cover mechanically.

17. The method as claimed in claim 15, further comprising the step of selecting the adhesive from a group consisting of a contact adhesive, a low ionic double-faced adhesive tape, a heat sensitive adhesive and a hot melt adhesive.

18. The method as claimed in claim 11, further comprising the step of compressing the resilient sheet between about five percent and twenty five percent of its thickness.

19. The method as claimed in claim 11, further comprising the step of compressing the resilient sheet between about 0.01 inch and about 0.05 inch.

20. The method as claimed in claim 11, further comprising the step of selecting the resilient layer so that it comprises a static dissipative cross-linked polyethylene foam.

21. A microelectronics transport tray as depicted and described herein.

22. A method of containing, protecting and transporting microelectronic components as depicted and described herein.
